(19) United States
(12) Patent Application Publication
(10) Pub. No.: US 2014/0242785 A1
(43) Pub. Date: Aug. 28, 2014

(54) SEMICONDUCTOR FILMS ON SAPPHIRE GLASS

(71) Applicant: Ashok Chaudhari, Briarcliff Manor, NY (US)

(72) Inventor: Ashok Chaudhari, Briarcliff Manor, NY (US)

(73) Assignee: SOLAR-TECTIC, LLC, Briarcliff Manor, NY (US)

(21) Appl. No.: 14/271,673

(22) Filed: May 7, 2014

Related U.S. Application Data
(60) Provisional application No. 61/831,719, filed on Jun. 6, 2013.

(51) Int. Cl. H01L 21/02

(52) U.S. Cl. CPC H01L 21/0242; H01L 21/02532; H01L 21/02546; H01L 21/02598
USPC 438/479

(57) ABSTRACT

A method is disclosed for growing large grain to single crystalline semiconductor films on inexpensive glass substrates. The method comprises deposition of semiconductor films from a eutectic melt on sapphire glass

### PRIORITY AND RELATED APPLICATIONS

This application claims priority to U.S. Provisional Patent Application Ser. No. 61/831,719, filed Jun. 6, 2013, entitled “Silicon Film on Sapphire Glass,” which is incorporated by reference in its entirety.

### FIELD OF THE INVENTION

The present invention is related to producing large grained to single crystal semiconductor films, such as silicon films, for producing articles such as photovoltaic and other electronic devices.

### BACKGROUND OF THE INVENTION

It has been a long standing goal in the materials science community to produce large grained to single crystal semiconductor films on inexpensive substrates for cost effective electronic devices, such as photovoltaic cells and field effect transistors. One approach to solving this problem has been to deposit buffer layers such as Magnesium Oxide (MgO) and Aluminum Oxide (Al203) on glass or metal tapes thus creating a crystalline template, followed by deposition of a thin semiconductor film, such as silicon which has been induced to grow epitaxially or with strong texture. Yet, as of the date of this disclosure, large grained to single crystalline semiconductor films have not successfully been grown with quality equal to or comparable to single crystal substrates such as those used in the microelectronics industry.

Recent progress in materials research and development has however now opened up a new way to achieving the goal of depositing large grained to single crystalline semiconductor films on inexpensive glass, such as soda-lime glass. This is due to the invention of two important steps:
1.Heteroepitaxial deposition of silicon film on Al₂O₃ (sapphire) below the softening temperature of soda-lime glass (−600° C.) as disclosed in US 2009/0297774 (Chaudhari et al).
2.Single crystalline (Al₂O₃) sapphire glass is disclosed in US 2013/0236699 (Prest et al).

Here we disclose a way of depositing large grained to single crystalline semiconductor films. The act of deposition consists of combining the above two inventions, thus achieving a cost effective method of depositing large grained to single crystalline semiconductor films on inexpensive glass for photovoltaic and other electronic applications.

### OBJECT OF THE INVENTION

It is an object of the present invention to provide large grained to single crystal semiconductor films, in particular silicon films, for photovoltaic technology and other semiconductor devices.

It is yet another object of this invention to provide single crystal or large grained semiconductor films, in particular semiconductor films, at low temperatures. For example, if silicon films are used, the growth temperature is between 450° C. and 650° C.

It is yet another object of this invention to provide single crystal or large grained semiconductor films, particularly silicon films, on inexpensive (soda-lime) glass consisting of a sapphire (Al₂O₃) crystal layer.

It is yet another object of this invention to provide single crystal or large grained semiconductor films, particularly silicon films, on soda-lime glass, on which there is a large grained sapphire (Al₂O₃) crystal layer.

It is yet another object of this invention to provide single crystal or large grained semiconductor films, particularly silicon films, on sapphire glass.

### SUMMARY OF THE INVENTION

In accordance with one aspect of the present invention, the foregoing and other objects can be achieved by patent publication US2009/0297774, in which a method for depositing semiconductor films such as silicon on sapphire (Al₂O₃) and soda-lime glass at low temperature, below the softening point of soda-lime glass, is disclosed.

In accordance with another aspect of the present invention, the foregoing and other objects can be achieved by depositing a semiconductor film, such as silicon, on sapphire glass, or on a glass substrate provided with an Al₂O₃ layer on the surface of the glass disclosed in patent publication US 2013/0236699.

The combination of these two steps enables a new method avoiding the necessity of an Al₂O₃ (sapphire) buffer template layer, or any other layers, which is more cost effective and could allow for the first time the deposition of a single crystalline to large grained semiconductor film, such as silicon, on glass, for highly efficient and cost effective electronic devices.

### DETAILED DESCRIPTION OF THE INVENTION

A method for growing large grain to single crystalline semiconductor films on inexpensive substrates, such as soda-lime glass, is provided. A sapphire glass substrate consisting of a large grain or single crystalline layer or coating of sapphire (crystalline Al₂O₃) on the surface of the glass is held at a constant temperature in a vacuum system. The temperature will vary according to the glass used. For example, soda-lime glass would require a temperature of at most 600° C. Next, a thin metal layer is deposited on the sapphire glass by any of the methods known in the art, for example electron beam evaporation. Many different metals can be used, but must all be able to form a eutectic alloy with the semiconductor to be deposited. An example of such an alloy would be aluminum and silicon (Al—Si). After the metal film is deposited, a semiconductor film is then deposited on the metal film also by e-beam. The resulting eutectic alloy allows for the precipitation of the semiconductor film onto the sapphire glass. The metal component of the alloy rises to the surface of the film now deposited on the sapphire glass and upon cooling can be etched away. A thicker semiconductor film can now be deposited on the semiconductor on sapphire glass substrate and used for various electronic applications, such as solar cells.

### Example of the Invention

A good high vacuum system with two electron beam guns is used to deposit aluminum and silicon independently. A sapphire glass substrate consisting of a layer or coating of crystalline Al₂O₃ is held at a temperature of 575° C. This is a nominal temperature. It is understood to one skilled in the art that lower or higher temperatures can also be used depending on the softening temperature of the glass substrate. A thin Al film of 6 mm thick is deposited on the sapphire glass followed by a 100 nm thick silicon deposition and a two phase region comprising of solid silicon and a liquid Si—Al mixture is reached.

The deposition is stopped and the sample is slowly cooled to room temperature. Aluminum diffuses through the silicon film, driven by its lower surface energy relative to silicon. The silicon film is heteroepitaxially aligned by the Al₂O₃ surface on the glass. The aluminum film on the surface can be etched chemically by well-known processes to leave behind a silicon film. The surface of this film can now be used for further growth of epitaxial films either for photovoltaic devices or other electronic devices such as field effect transistors.

1. A method of growing semiconductor film comprising steps of:
providing a sapphire glass substrate; and
depositing a semiconductor film on the glass substrate, the semiconductor film being deposited from a eutectic liquid, said semiconductor being deposited on said sapphire glass substrate below a softening temperature of the glass substrate, said sapphire glass substrate comprised partly of crystalline Al₂O₃.

2. The method of claim 1 where said sapphire glass consists of a layer of crystalline Al₂O₃ on the surface of the glass.

3. The method of claim 1 where said crystalline Al₂O₃ is single crystalline.

4. The method of claim 1 where said crystalline Al₂O₃ is polycrystalline.

5. The method of claim 1 where said semiconductor film single crystalline.

6. The method of claim 1 where said semiconductor film is heteroepitaxially aligned with the Al₂O₃ layer on or in the sapphire glass.

7. The method of claim 1 where said semiconductor film is large grained.

8. The method of claim 1 where said semiconductor film is highly textured.

9. The method of claim 1 where said semiconductor film is silicon.

10. The method of claim 1 where said semiconductor film in GaAs.

11. The method of claim 1 where said single crystalline Al₂O₃ layer is c-axis.
